(19) United States
(12) Patent Application Publication
(10) Pub. No.: US 2024/0090155 A1
(43) Pub. Date: Mar. 14, 2024

(54) Slide Rail Buffer Structure

(71) Applicant: Asia Pacific CIS (Wuxi) Co. Ltd., Wuxi (CN)

(72) Inventor: Juanjuan Xie, Wuxi (CN)

(21) Appl. No.: 18/465,729

(22) Filed: Sep. 12, 2023

(30) Foreign Application Priority Data
Sep. 13, 2022 (CN) 202222419765.1

(51) Int. Cl. H05K 7/14

(52) U.S. Cl. CPC H05K 7/1489; H05K 7/203

(57) ABSTRACT

The present utility model relates to a slide rail buffering structure belonging to the field of slide rails. The buffering structure comprises a housing, guide pins, elastic members, a buffering piece, buffer chambers, liquid injection holes and a liquid coolant. When the slide rail is open, due to the fact that the elastic members are no longer compressed, the guide pins and the buffering piece are pushed to move outwards, the server's liquid coolant enters the buffer chambers through the liquid injection holes in the tail portion of the housing and fills up the chambers, and the buffering piece stops moving when abutting against a first position-limiting block; whereas when the slide rail is closed, the tail portion of a second rail abuts against the buffering piece to generate an inward thrust, pushing the buffering piece and the guide pins to move inwards, and the guide pins press against the buffering piece and the liquid coolant in the buffer chambers, thereby forming a buffer. In this way, the present utility model is made to be structurally compact, rational, easy to operate, enabling automatic buffering, thereby preventing collision damage that may be caused by excessive impact during operation, reducing accidental damage that may be caused by undesirable operation, and prolonging the server's lifespan.

### TECHNICAL FIELD

The present utility model relates to a buffering structure and, more particularly, to a slide rail buffering structure belonging to the field of slide rails.

### BACKGROUND

Immersion liquid-cooled servers are servers whose server main boards, CPUs, internal memories and other components generating high heat are completely immersed in refrigerants, and under working conditions, these various heat generating components would generate heat and cause temperature rise of the refrigerants.

When the temperature of a refrigerant rises to the boiling point corresponding to the system pressure, the refrigerant working medium undergoes a phase change, changing from liquid state to gaseous state, and the transfer of heat is realized by absorbing heat through the heat of vaporization. This technology of cooling through the refrigerant absorbing heat is referred to as “phase change liquid cooling technology”.

Immersion phase change liquid cooling technology uses liquid phase change to directly take away the heat, which reduces the thermal resistance of the heat transfer process. Compared to cold plate liquid cooling, immersion phase change liquid cooling technology provides higher heat transfer efficiency and is the most energy-saving and efficient emerging refrigeration mode in China.

As an important accessory of immersion server slide rail, the demand for it will be increasing. In comparison with conventional air-cooled server slide rails, liquid-cooled servers can be installed vertically on the ground. In this scenario, after its installation the server is prone to directly impacting the blocking point due to operational errors, causing internal and external damages to itself.

### SUMMARY OF THE UTILITY MODEL

Purpose of the utility model: to provide a slide rail buffering structure to solve the abovementioned problems.

Technical solution: A slide rail buffering structure comprising: a first rail and a second rail immersed in a liquid coolant of a server, and a buffer assembly fixedly mounted at an end of the first rail.

In a further embodiment, the buffer assembly is composed of a housing, buffering portions disposed in the housing, a buffering piece mounted on the head portions of the buffering portions, and a liquid coolant disposed in the housing.

In a further embodiment, each of the buffering portions includes a guide pin and an elastic member.

In a further embodiment, the housing is relatively fixedly mounted on the first rail, and with buffer chambers provided therein, liquid injection holes communicating respectively with the buffer chambers are provided at the bottom of the housing, the guide pins and the elastic members are provided in the buffer chambers, respectively, and each of the elastic members is located between the guide pin and the bottom surface of the buffer chamber, respectively.

In a further embodiment, the buffering piece is sleeved on the head portions of the guide pins, the buffering piece is made of resilient material.

In a further embodiment, the housing and the buffering piece are each provided with a groove, when the slide rail is closed, the buffering piece is located in the groove of the housing, and the tail portion of the second rail is located in the groove of the buffering piece; an outer surface of the buffering piece has a clearance fit with an inner surface of the groove of the housing, and an inner surface of the buffering piece has a clearance fit with an outer surface of the second rail.

In a further embodiment, the buffer chambers have a depth not greater than the length of the housing.

In a further embodiment, the first rail and the second rail are slidingly connected with the first rail provided with a ball sliding trestle and the second rail located in the ball sliding trestle, a first position-limiting block is provided between the ball sliding trestle and the buffering piece, a stopper block is provided at the head portion of the first rail, with the ball sliding trestle located between the first position-limiting block and the stopper block, and a second position-limiting block is provided at the head portion of the second rail.

In a further embodiment, an anti-detachment paddle is provided on an inner side of the tail portion of the second rail, an anti-detachment block is provided at the head portion of the first rail and when the second rail is extended, the anti-detachment block is located in a snap ring of the anti-detachment paddle, indicating the second rail is at a maximum extension distance.

In a further embodiment, the centers of the buffer chambers and the centers of the liquid injection holes are coaxial, respectively.

In a further embodiment, when the buffering piece is extended to the maximum distance, the buffering piece is in surface contact with the two arms at the end of the first rail.

Beneficial effects: the present utility model relates to a buffering structure and, more particularly, to a slide rail buffering structure belonging to the field of slide rails. The present utility model comprises a first rail and a second rail immersed in a liquid coolant of a server, and a buffer assembly fixedly mounted at an end of the first rail; the buffer assembly is composed of a housing, buffering portions disposed in the housing, a buffering piece mounted on the head portions of the buffering portions, and a liquid coolant disposed in the housing; wherein each of the buffering portions includes a guide pin and an elastic member which are mounted in the buffer chamber in the housing, liquid injection holes communicating respectively with the buffer chambers are provided at the bottom of the housing. When the slide rail is open, due to the fact that the elastic members are no longer compressed, the guide pins and the buffering piece are pushed to move outwards, the server's liquid coolant enters the buffer chambers through the liquid injection holes in the tail portion of the housing and fills up the chambers, and the buffering piece stops moving when abutting against a first position-limiting block; whereas when the slide rail is closed, the tail portion of a second rail abuts against the buffering piece to generate an inward thrust, pushing the buffering piece and the guide pins to move inwards, and the guide pins press against the buffering piece and the liquid coolant in the buffer chambers, thereby forming a buffer. In this way, the present utility model is made to be structurally compact, rational, easy to operate, enabling automatic buffering, thereby preventing collision damage that may be caused by excessive impact during operation, reducing accidental damage that may be caused by undesirable operation, and prolonging the server's lifespan.

### BRIEF DESCRIPTION OF THE DRAWINGS

FIG. 1 is an axonometric view of a slide rail of the present utility model when it is stretched out.

FIG. 2 is a front view of the slide rail of the present utility model when it is stretched out.

FIG. 3 is a rear view of the slide rail of the present utility model when it is stretched out.

FIG. 4 is a front view of the slide rail of the present utility model when it is closed.

FIG. 5 is an axonometric view of a buffer assembly of the present utility model.

FIG. 6 is a sectional view of the buffer assembly of the present utility model.

FIG. 7 is a partial schematic view of the slide rail of the present utility model when it is stretched out.
Reference numerals: 1 denotes first rail, 2 denotes second rail, 3 denotes buffer assembly, 4 denotes housing, 5 denotes buffering portion, 6 denotes buffering piece, 7 denotes guide pin, 8 denotes elastic member, 9 denotes buffer chamber, 10 denotes liquid injection hole, 11 denotes groove, 12 denotes ball sliding trestle, 13 denotes first position-limiting block, 14 denotes stopper block, 15 denotes second position-limiting block, 16 denotes anti-detachment paddle, and 17 denotes anti-detachment block.

### DETAILED DESCRIPTION

The technical solution of the present utility model will be described in more complete detail below with reference to the accompanying drawings, and it is apparent that those described are some rather than all embodiments of the present utility model. All other embodiments obtained by persons skilled in the art based on the embodiments of the present utility model without innovative labor shall fall within the scope of protection of the present utility model.

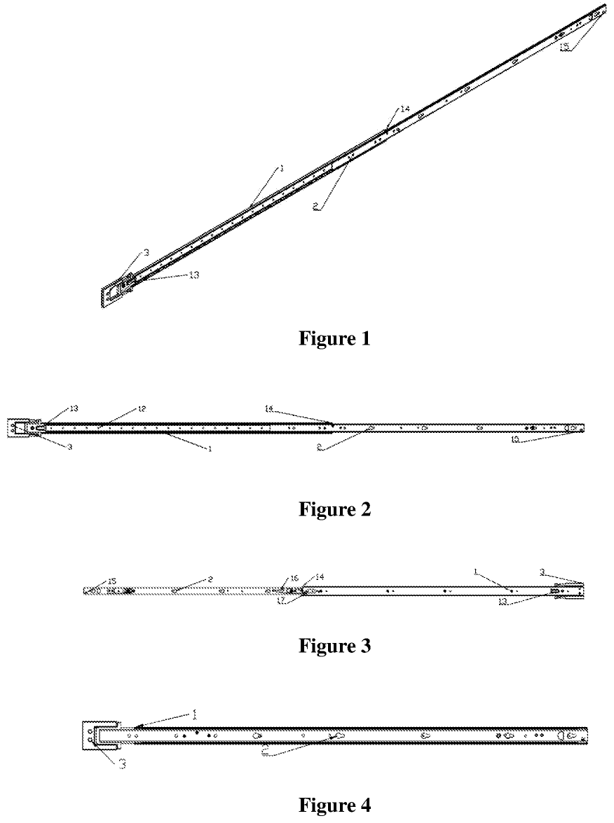

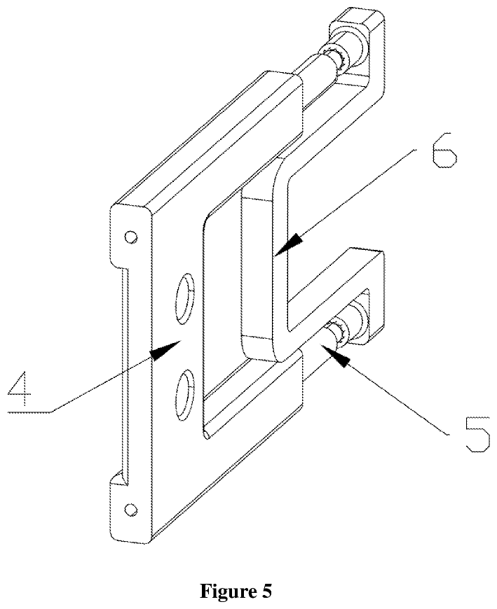

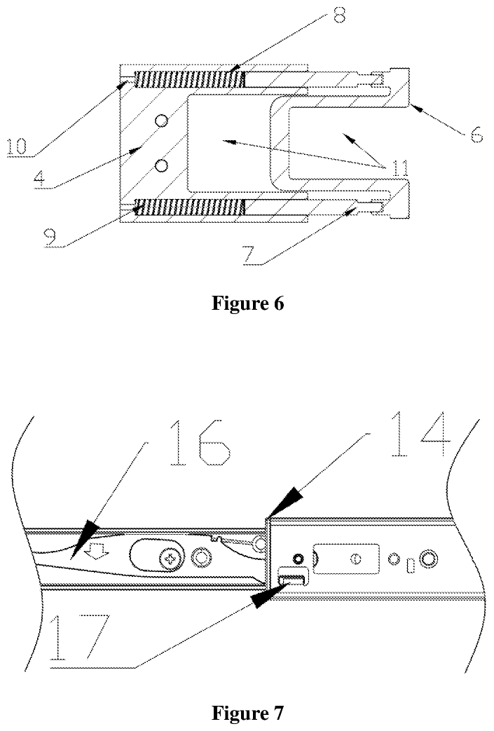

As shown in FIGS. 1 to 7, a slide rail buffering structure comprises: a first rail 1 and a second rail 2 immersed in a liquid coolant of a server, and a buffer assembly 3 fixedly mounted at an end of the first rail 1.

### Embodiment 1

The buffer assembly 3 is composed of a housing 4, guide pins 7, elastic members 8, a buffering piece 6, buffer chambers 9, liquid injection holes 10 and a liquid coolant.

In one embodiment, the housing 4 is disposed in the buffering portions 5, the buffering piece 6 is mounted on the head portions of the buffering portions 5, and the liquid coolant is disposed in the housing 4.

In one embodiment, each of the buffering portions 5 includes a guide pin 7 and an elastic member 8.

In one embodiment, the housing 4 is relatively fixedly mounted on the first rail 1, and with buffer chambers 9 provided therein, liquid injection holes 10 communicating respectively with the buffer chambers 9 are provided at the bottom of the housing 4, the guide pins 7 and the elastic members 8 are provided in the buffer chambers 9, respectively, and each of the elastic members 8 is located between the guide pin 7 and the bottom surface of the buffer chamber 9, respectively.

In one embodiment, the buffering piece 6 is sleeved on the head portions of the guide pins 7, the buffering piece 6 is made of resilient material.

In one embodiment, the housing 4 and the buffering piece 6 are each provided with a groove 11, when the slide rail is closed, the buffering piece 6 is located in the groove 11 of the housing 4, and the tail portion of the second rail 2 is located in the groove 11 of the buffering piece 6; an outer surface of the buffering piece 6 has a clearance fit with an inner surface of the groove 11 of the housing 4, and an inner surface of the buffering piece 6 has a clearance fit with an outer surface of the second rail 2.

In one embodiment, the buffer chambers 9 have a depth not greater than the length of the housing 4.

### Embodiment 2

In one embodiment, the first rail 1 and the second rail 2 are slidingly connected with the first rail 1 provided with a ball sliding trestle 12 and the second rail 2 located in the ball sliding trestle 12, a first position-limiting block 13 is provided between the ball sliding trestle 12 and the buffering piece 6, a stopper block 14 is provided at the head portion of the first rail 1, with the ball sliding trestle 12 located between the first position-limiting block 13 and the stopper block 14, and a second position-limiting block 15 is provided at the head portion of the second rail 2.

In one embodiment, an anti-detachment paddle 16 is provided on an inner side of the tail portion of the second rail 1, an anti-detachment block 17 is provided at the head portion of the first rail 1 and when the second rail 2 is extended, the anti-detachment block 17 is located in a snap ring of the anti-detachment paddle 16, indicating the second rail 2 is at a maximum extension distance.

In one embodiment, the centers of the buffer chambers 9 and the centers of the liquid injection holes 10 are coaxial, respectively.

In one embodiment, when the buffering piece 6 is extended to the maximum distance, the buffering piece 6 is in surface contact with the two arms at the end of the first rail 1.

Operating principles: the present utility model may have the following two working situations:

When opening the slide rail, the worker pulls the second rail 2, and due to the outward pulling force, the second rail 2 is urged to slide outwards through the ball sliding trestle 12 disposed on the first rail 1. When the snap ring on the anti-detachment paddle 16 is in snap connection with the anti-detachment block 17, thus resulting in braking, indicating the slide rail has reached the maximum extension distance at this time, whereas at the same time, when the second rail 2 moves outwards, the buffer assembly 3 is also working. Since the elastic members 8 in the buffer chambers 9 are no longer compressed, the guide pins 7 and the buffering piece 6 are pushed to move outwards, the server's liquid coolant enters the buffer chambers 9 through the liquid injection holes 10 in the tail portion of the housing 4 and fills up the chambers. When the buffering piece 6 abuts against the first rail 1 and is in surface contact with the two arms at the end of the first rail 1, indicating the buffering piece 6 has extended to the maximum distance and thereby ending the movement, at which time both the slide rail and the buffering piece 6 have extended to the maximum distance and thereby completed the opening of the slide rail.

When closing the slide rail, the worker plucks the anti-detachment paddle 16 downwards so that the anti-detachment block 17 at the head portion of the first rail 1 is pushed off the snap ring on the anti-detachment paddle 16, at which time the second rail 2 is pushed and due to the inward thrust, the second rail 2 is made to slide inwards through the ball sliding trestle 12 disposed on the first rail 1. When the tail portion of the second rail 2 enters the groove 11 of the buffering piece 6 and abuts against the buffering piece 6, the second rail 2 drives the buffering piece 6 to move inwards, and in turn the buffering piece 6 pushes the guide pins 7 to move inwards, and the guide pins 7 press against the elastic members 8 and the liquid coolant in buffer chambers 9, thereby forming a buffer. When the buffering piece 6 enters the groove 11 of the housing 4 and abuts against the groove 11, buffering and braking are completed. Whereas at the same time, the tail portion of the second rail 2 is in contact with the first position-limiting block 13, and the head portion of the second rail 2 and the first position-limiting block 13 are in contact with the stopper block 14 on the first rail 1, thereby achieving braking and position-limiting effects. At this time, both the slide rail and the buffering piece 6 have returned to their respective positions, thereby having completed closing of the slide rail.

Apparently, the foregoing embodiments are merely intended to be illustrative of the present utility model rather than limiting it. For those of ordinary skill in the art, changes or alterations of other forms can be made based on the above description. Since it is neither desirable nor feasible to exhaustively enumerate all possible embodiments, any apparent changes or alterations derived from the present utility model shall fall within the scope of protection thereof.

What is claimed is:

1. A slide rail buffering structure comprising:
a first rail and a second rail immersed in a liquid coolant of a server, and a buffer assembly fixedly mounted at an end of the first rail;
the buffer assembly is composed of a housing, buffering portions disposed in the housing, a buffering piece mounted on the head portions of the buffering portions, and a liquid coolant disposed in the housing;
each of the buffering portions includes a guide pin and an elastic member.

2. The slide rail buffering structure according to claim 1, characterized in that:
the housing is relatively fixedly mounted on the first rail, and with buffer chambers provided therein, liquid injection holes communicating respectively with the buffer chambers are provided at the bottom of the housing, the guide pins and the elastic members are provided in the buffer chambers, respectively, and each of the elastic members is located between the guide pin and the bottom surface of the buffer chamber, respectively.

3. The slide rail buffering structure according to claim 1, characterized in that:
the buffering piece is sleeved on the head portions of the guide pins, the buffering piece is made of resilient material.

4. The slide rail buffering structure according to claim 1, characterized in that:
the housing and the buffering piece are each provided with a groove, when the slide rail is closed, the buffering piece is located in the groove of the housing, and the tail portion of the second rail is located in the groove of the buffering piece; an outer surface of the buffering piece has a clearance fit with an inner surface of the groove of the housing, and an inner surface of the buffering piece has a clearance fit with an outer surface of the second rail.

5. The slide rail buffering structure according to claim 2, characterized in that:
the buffer chambers have a depth not greater than the length of the housing.

6. The slide rail buffering structure according to claim 1, characterized in that:
the first rail and the second rail are slidingly connected with the first rail provided with a ball sliding trestle and the second rail located in the ball sliding trestle, a first position-limiting block is provided between the ball sliding trestle and the buffering piece, a stopper block is provided at the head portion of the first rail, with the ball sliding trestle located between the first position-limiting block and the stopper block, and a second position-limiting block is provided at the head portion of the second rail.

7. The slide rail buffering structure according to claim 6, characterized in that:
an anti-detachment paddle is provided on an inner side of the tail portion of the second rail, an anti-detachment block is provided at the head portion of the first rail and when the second rail is extended, the anti-detachment block is located in a snap ring of the anti-detachment paddle, indicating the second rail is at a maximum extension distance.

8. The slide rail buffering structure according to claim 6, characterized in that:
the centers of the buffer chambers and the centers of the liquid injection holes are coaxial, respectively.

9. The slide rail buffering structure according to claim 1, characterized in that:
when the buffering piece is extended to the maximum distance, the buffering piece is in surface contact with the two arms at the end of the first rail.
